(19) United States
(12) Patent Application Publication
(10) Pub. No.: US 2021/0161037 A1
(43) Pub. Date: May 27, 2021

(54) NOISE SUPPRESSION SHEET

(71) Applicant: TDK CORPORATION, Tokyo (JP)

(72) Inventors: Takashi YAMADA, Tokyo (JP); Atsushi SATO, Tokyo (JP); Hideharu MORO, Tokyo (JP)

(73) Assignee: TDK CORPORATION, Tokyo (JP)

(21) Appl. No.: 16/694,032

(22) Filed: Nov. 25, 2019

(51) Int. Cl. H05K 9/00; H01F 1/047; C22C 19/03; B32B 15/01

(52) U.S. Cl. CPC H05K 9/0075; H01F 1/047; B32B 2307/102; B32B 15/01; C22C 19/03

(57) ABSTRACT

A noise suppression sheet includes a metal magnetic layer composed of a FeNi alloy containing 78 to 84 wt % of Ni, the metal magnetic layer having 2 to 8 wt % of Si added thereto. The noise suppression sheet achieves excellent magnetic shielding characteristics. In the noise suppression sheet, particularly, a high electrical resistivity of 70 to 115 μΩ·cm is achieved in the metal magnetic layer, high magnetic permeability is maintained in a high frequency band of about 1 MHz to 10 MHz, and the frequency dependence of the dielectric constant is reduced.

### TECHNICAL FIELD

The present disclosure relates to a noise suppression sheet.

### BACKGROUND

In recent years, along with increasing operation speed of a digital circuit in an electronic apparatus, erroneous operation of the electronic apparatus or an adverse effect on a human body caused by noise such as electromagnetic waves generated from the circuit has been deepening. For this reason, development of a noise suppression sheet for suppressing (blocking) noise has been progressed.

For example, Japanese Unexamined Patent Publication No. 2004-153213 discloses a noise suppression sheet including a FeNi alloy foil. The embodiment of the present literature shows that the FeNi alloy foil has a composition of Fe-78 wt % Ni-4 wt % Mo-wt % Si. Japanese Patent No. 2991220 and Japanese Unexamined Patent Publication No. S62-199004 disclose techniques for adding various elements to a FeNi alloy.

### SUMMARY

The present inventors have performed research on the magnetic shielding characteristics of the noise suppression sheet, and as a result, have newly found a technology that achieves excellent magnetic shielding characteristics even in a high frequency band.

The present disclosure provides a noise suppression sheet with improved magnetic shield characteristics.

The noise suppression sheet according to an embodiment of the present disclosure includes a metal magnetic layer composed of a FeNi alloy containing 78 to 84 wt % of Ni, the metal magnetic layer having 2 to 8 wt % of Si added thereto.

In the noise suppression sheet according to another aspect, the thickness of the metal magnetic layer is less than 10 μm.

The noise suppression sheet according to another aspect further includes a non-magnetic metal layer laminated on the metal magnetic layer.

In the noise suppression sheet according to another embodiment, the electrical resistivity of the metal magnetic layer is 70 to 115 μΩ·cm.

### BRIEF DESCRIPTION OF THE DRAWINGS

FIG. 1 is a schematic sectional view showing one embodiment of a noise suppression sheet; and

FIG. 2 is a table showing evaluation results according to Examples.

### DETAILED DESCRIPTION

Some embodiments of the present disclosure are described below, with reference as necessary to the drawings. However, the present disclosure is not limited to the following embodiments.

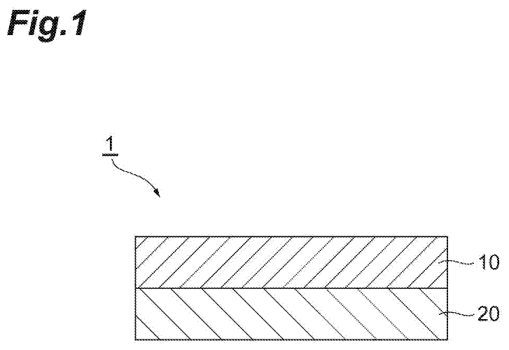

FIG. 1 is a schematic sectional view showing one embodiment of a noise suppression sheet. A noise suppression sheet 1 shown in FIG. 1 includes a metal magnetic layer 10 and a non-magnetic metal layer 20 laminated on the metal magnetic layer 10. From the viewpoint of thinning, the noise suppression sheet 1 is designed so that its thickness is 20 μm or less.

The metal magnetic layer 10 is a foil or thin film composed of magnetics, and is composed of a FeNi alloy (permalloy) including Fe and Ni. In the present embodiment, the FeNi alloy constituting the metal magnetic layer 10 contains 78 to 84 wt % of Ni and 16 to 22 wt % of Fe. In addition, 2 to 8 wt % of Si is added to the metal magnetic layer 10. The metal magnetic layer 10 has a high magnetic permeability and can function as a magnetic shield layer that absorbs noise.

The thickness of the metal magnetic layer 10 is designed to be 10 μm or less (5 μm as an example) in the present embodiment. From the viewpoint of thinning the noise suppression sheet 1, the thickness of the metal magnetic layer 10 may be 7 μm or less or 5 μm or less. From the viewpoint of more effectively absorbing noise, the thickness of the metal magnetic layer 10 may be 0.5 μm or more, 1 μm or more, or 3 μm or more.

The metal magnetic layer 10 is designed to have a high electrical resistivity, and the electrical resistivity of the metal magnetic layer 10 according to the present embodiment is 70 to 115 μΩ·cm (95 μΩ·cm as an example).

When the metal magnetic layer 10 is a foil (or sheet), the metal magnetic layer 10 can be obtained by rolling. When the metal magnetic layer 10 is a thin film, the metal magnetic layer 10 can be obtained by coating or plating (electrolytic plating or electroless plating).

The non-magnetic metal layer 20 is a foil or thin film composed of a non-magnetic metal. Examples of the non-magnetic metal constituting the non-magnetic metal layer 20 include Cu, Al, Sn, and Bi. The non-magnetic metal layer 20 may be composed of a single non-magnetic metal or a plurality of non-magnetic metals having different metal species. The non-magnetic metal layer 20 according to the present embodiment is composed of at least one selected from the group consisting of Cu and Al. The non-magnetic metal layer 20 functions as an electromagnetic wave shield that reflects electromagnetic noise.

The thickness of the non-magnetic metal layer 20 may be 1 μm or more or 2 m or more from the viewpoint of effectively reflecting electromagnetic noise, and may be 4 μm or less, 3 μm or less, or 2 μm or less from the viewpoint of thinning the noise suppression sheet 1.

When the non-magnetic metal layer 20 is a foil (or sheet), the non-magnetic metal layer 20 can be obtained by rolling. When the non-magnetic metal layer 20 is a thin film, the non-magnetic metal layer 20 can be obtained by electrolytic processing or vapor deposition.

The method of obtaining the noise suppression sheet 1 in which the metal magnetic layer 10 and the non-magnetic metal layer 20 overlap is not particularly limited, and various methods can be employed.

For example, when the metal magnetic layer 10 and the non-magnetic metal layer 20 are both foils, the noise suppression sheet 1 can be formed by bonding the metal magnetic layer 10 and the non-magnetic metal layer 20 together.

When the metal magnetic layer 10 is a foil, the noise suppression sheet 1 can be formed by forming a thin non-magnetic metal layer 20 on the metal magnetic layer 10 due to coating or plating.

When the non-magnetic metal layer 20 is a foil, the noise suppression sheet 1 can be formed by forming a thin metal magnetic layer 10 on the non-magnetic metal layer 20 due to electrolytic processing or vapor deposition.

The method of adding Si to the metal magnetic layer 10 is not particularly limited, and various methods can be employed. For example, Si can be added to the metal magnetic layer 10 by diffusing Si into the FeNi alloy constituting the metal magnetic layer 10. Specifically, Si can be diffused into the FeNi alloy plating film by forming a SiO₂ film on the FeNi alloy plating film to be the metal magnetic layer 10 and then by performing a reduction treatment. A TEOS solution (Si(OC₂H)₄ solution) can be used to form the above SiO₂ film. The above reduction treatment can be performed by a heat treatment in a hydrogen atmosphere using a reducing agent.

The above noise suppression sheet 1 can absorb and suppress noise (magnetism, electromagnetic waves, and the like) generated from a circuit or the like in an electronic component by being mounted on the electronic component or the like. In the noise suppression sheet 1, noise is absorbed by the metal magnetic layer 10. Noise that is transmitted without being absorbed by the metal magnetic layer 10 can be reflected by the non-magnetic metal layer 20 and can be absorbed again by the metal magnetic layer 10, and hence the noise suppression sheet 1 can suppress noise effectively.

Moreover, according to the noise suppression sheet 1, an excellent magnetic shielding characteristic is achievable. In the noise suppression sheet 1, particularly, a high electrical resistivity of 70 to 115 μΩ·cm is achieved in the metal magnetic layer 10, high magnetic permeability is maintained even in a high frequency band of about 1 MHz to 10 MHz, and the frequency dependence of the dielectric constant is reduced.

The noise suppression sheet 1 has high magnetic shield characteristics, and hence it can be thinned while maintaining practically sufficient magnetic shield characteristics as a noise suppression sheet.

### EXAMPLES

The present disclosure is more specifically described below by providing Examples. However, the present disclosure is not limited to these Examples.

### [Preparation of Noise Suppression Sheet]

### Example 1

As Example 1, a noise suppression sheet was prepared, the sheet consisting of: a metal magnetic layer composed of a FeNi alloy containing 80 wt % of Ni and 20 wt % of Fe and having 3 wt % of Si added; and a non-magnetic metal layer laminated on the metal magnetic layer. The thickness of the metal magnetic layer was 5 m. A Cu layer with a thickness of 2 m was used as the non-magnetic metal layer.

A TEOS solution was used for adding Si to the metal magnetic layer. As the TEOS solution, a TEOS solution having a composition of 6 wt % TEOS-30 wt % H₂O-0.5 wt % NaOH-63.5 wt % C₂H₅OH was used. On the metal magnetic layer having the form of a plating film, the TEOS solution was applied in an amount such that the layer has 3 wt % of Si added, and then it was maintained at 80° C. for 1 hour, and the SiO₂ film was formed on the metal magnetic layer. The metal magnetic layer with the formed SiO₂ film was subjected to a heat treatment at 650° C. for 2 hours in a hydrogen atmosphere by using a reducing agent as a reduction treatment to obtain a metal magnetic layer with Si diffused at a ratio of 3 wt %.

### Examples 2 to 4

As Examples 2 to 4, a noise suppression sheet was prepared, the sheet consisting of: a metal magnetic layer composed of a FeNi alloy containing 80 wt % of Ni and 20 wt % of Fe and having 5 wt %, 6 wt %, and 8 wt %, respectively, of Si added; and a non-magnetic metal layer laminated on the metal magnetic layer. In Examples 2 to 4, a predetermined ratio of Si was diffused into the metal magnetic layer in the same manner as in Example 1 except that the amount of the TEOS solution applied in Example 1 was changed.

### Comparative Example 1

As Comparative Example 1, a noise suppression sheet was prepared, the sheet consisting of: a metal magnetic layer composed of a FeNi alloy containing 80 wt % of Ni and 20 wt % of Fe and having no Si added; and a non-magnetic metal layer laminated on the metal magnetic layer.

### Comparative Examples 2 to 3

As Comparative Examples 2 and 3, a noise suppression sheet was prepared, the sheet consisting of: a metal magnetic layer composed of a FeNi alloy containing 80 wt % of Ni and 20 wt % of Fe and having 1 wt % and 9 wt %, respectively, of Si added; and a non-magnetic metal layer laminated on the metal magnetic layer. In Comparative Examples 2 and 3, a predetermined ratio of Si was diffused into the metal magnetic layer in the same manner as in Example 1 except that the amount of the TEOS solution applied in Example 1 was changed.

### [Evaluation of Noise Suppression Sheet]

### (Measurement of Electrical Resistivity)

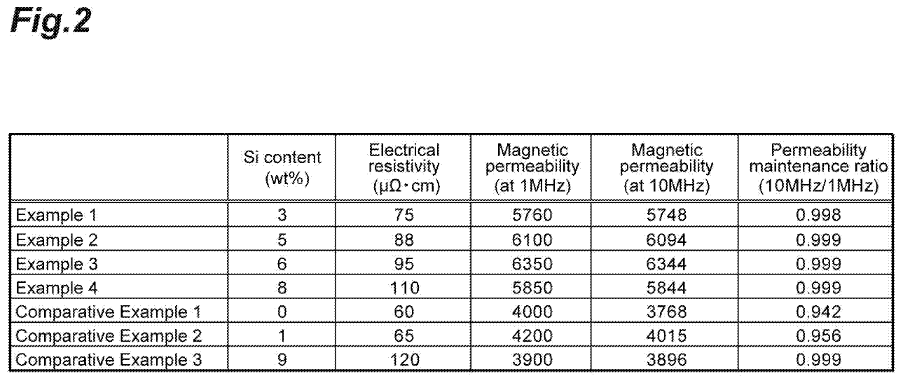

For each of the noise suppression sheet obtained in Examples 1 to 4 and the noise suppression sheet obtained in Comparative Examples 1 to 3, the electrical resistivity [μΩ·cm] of the metal magnetic layer was measured. The results are shown in table of FIG. 2.

### (Measurement of Magnetic Permeability and Permeability Maintenance Ratio)

The noise suppression sheet obtained in Examples 1 to 4 and the noise suppression sheet obtained in Comparative Examples 1 to 3 were processed like a ring, and the frequency characteristics of magnetic permeability were measured using an impedance analyzer. The frequency characteristics were confirmed, and the magnetic permeability at 1 MHz and 10 MHz was read respectively. In addition, the ratio of the magnetic permeability in 10 MHz to the magnetic permeability in 1 MHz was determined as a permeability maintenance ratio. The results are shown in table of FIG. 2.

As shown in table of FIG. 2, in all of Examples 1 to 4 where 2 to 8 wt % of Si is added to the metal magnetic layer, a high electrical resistivity of 70 to 115 μΩ·cm, a high magnetic permeability at 1 MHz and 10 MHz, and a high permeability maintenance ratio were obtained. In Comparative Example 1 where no Si is added to the metal magnetic layer, the magnetic permeability value was low and the electrical resistivity was low, and hence the permeability maintenance ratio was low. In Comparative Example 2 where the Si content is less than 2 to 8 wt %, the increase ratio of the magnetic permeability was low and the electrical resistivity was low, and hence the permeability maintenance ratio was low. In Comparative Example 3 where the Si content is more than 2 to 8 wt %, the permeability maintenance ratio was high due to the high electrical resistivity, but a sufficiently high magnetic permeability was not obtained due to too much Si content.

What is claimed is:

1. A noise suppression sheet comprising a metal magnetic layer composed of a FeNi alloy containing 78 to 84 wt % of Ni, the metal magnetic layer having 2 to 8 wt % of Si added thereto.

2. The noise suppression sheet according to claim 1, wherein a thickness of the metal magnetic layer is less than 10 μm.

3. The noise suppression sheet according to claim 1, further including a non-magnetic metal layer laminated on the metal magnetic layer.

4. The noise suppression sheet according to claim 2, further including a non-magnetic metal layer laminated on the metal magnetic layer.

5. The noise suppression sheet according to claim 3, wherein an electrical resistivity of the metal magnetic layer is 70 to 115 μΩ·cm.

6. The noise suppression sheet according to claim 4, wherein an electrical resistivity of the metal magnetic layer is 70 to 115 μΩ·cm.
